(19) United States
(12) Patent Application Publication
(10) Pub. No.: US 2011/0006779 A1
(43) Pub. Date: Jan. 13, 2011

(54) FLUX-GATE LEAKAGE CURRENT SENSOR

(75) Inventors: Masakazu KOBAYASHI, Saitama (JP); Konghui Yu, Saitama (JP)

Correspondence Address: HOLTZ, HOLTZ, GOODMAN & CHICK PC, 220 Fifth Avenue, 16TH Floor, NEW YORK, NY, 10001-7708, US

(73) Assignee: TAMURA CORPORATION, Tokyo (JP)

(21) Appl. No.: 12/831,302

(22) Filed: Jul. 7, 2010

(30) Foreign Application Priority Data
Jul. 9, 2009 (JP) 2009-162739

(51) Int. Cl. G01R 31/02

(52) U.S. Cl. 324/537

(57) ABSTRACT

A flux-gate leakage current sensor includes: an annular core; a coil wound around the core; a driving circuit which applies to the coil a voltage with a positive/negative symmetric rectangular wave so as to saturate a density of a magnetic flux of the coil while reversing a direction of the magnetic flux; a comparator circuit which compares a measured voltage changing according to a coil current flowing in the coil with a positive-side reference voltage and a negative-side reference voltage that are positive/negative symmetric to each other, and outputs a positive-side electric signal corresponding to a period in which the measured voltage is higher than the positive-side reference voltage and a negative-side electric signal corresponding to a period in which the measured voltage is lower than the negative-side reference voltage; and a determination circuit which compares the positive-side electric signal and the negative-side electric signal output from the comparator circuit.

### BACKGROUND OF THE INVENTION

1. Field of the Invention

The present invention relates to a flux-gate leakage current sensor for detecting an electric leak.

2. Description of the Related Art

As a device detecting a leak of electric current supplied from a power source to a load, Japanese Patent Application Laid-open No. 2000-2738 discloses a DC leakage current sensor. This device includes an annular core, to which a first detected conductor and a second detected conductor are inserted and around which a coil is wound.

A high-frequency current is supplied to the coil from a high-frequency output circuit, and an AC voltage at both ends of the coil is converted to a DC voltage by a rectifier circuit. Then, the DC voltage is compared with a reference voltage by a comparison circuit, and when the DC voltage is lower than the reference voltage, it is determined that an electric leak is occurring.

That is, this device detects the electric leak by utilizing the fact that, when the electric leak occurs, a density of a magnetic flux of the core saturates and an impedance of the coil decreases.

In the DC leakage current sensor disclosed in Japanese Patent Application Laid-open No. 2000-2738, a change in temperature of the core causes a change in magnetic permeability of the core to change the impedance of the coil, resulting in a change in the DC voltage as well. Further, since the density of the magnetic flux of the core presents a hysteresis, a value of the DC voltage changes even by the same amount of the leakage current, which might sometimes result in a failure in detecting the electric leak.

Therefore, it cannot be said that the DC leakage current sensor disclosed in Japanese Patent Application Laid-open No. 2000-2738 is excellent in temperature stability, and under an environment with a great temperature change, its leak detection accuracy might be lowered.

### SUMMARY OF THE INVENTION

It is an object of the present invention to provide a flux-gate leakage current sensor excellent in temperature stability.

According to one aspect of the present invention, there is provided a flux-gate leakage current sensor. The flux-gate leakage current sensor includes: an annular core to which a first electric wire and a second electric wire as targets of measurement are to be inserted; a coil wound around the core; a driving circuit which applies to the coil a voltage with a positive/negative symmetric rectangular wave so as to saturate a density of a magnetic flux of the coil while reversing a direction of the magnetic flux; a comparator circuit which compares a measured voltage changing according to a coil current flowing in the coil with a positive-side reference voltage and a negative-side reference voltage that are positive/negative symmetric to each other, and outputs a positive-side electric signal corresponding to a period in which the measured voltage is higher than the positive-side reference voltage and a negative-side electric signal corresponding to a period in which the measured voltage is lower than the negative-side reference voltage; and a determination circuit which compares the positive-side electric signal and the negative-side electric signal output from the comparator circuit.

Further scope of applicability of the present invention will become apparent from the detailed description given hereinafter. The detailed description and embodiments are only given as examples though showing preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will become more fully understood from the following detailed description and the accompanying drawings. The accompanying drawings only show examples and are not intended to restrict the present invention. In the accompanying drawings:

FIG. 1 is a block diagram showing a structure example of a flux-gate leakage current sensor of one embodiment;

FIG. 2 is an electric circuit diagram of the flux-gate leakage current sensor in FIG. 1;

FIG. 3 is a timing chart in the electric circuit in FIG. 2 when there is no electric leak, FIG. 3(a) showing a time change of a coil current Ic detected by a current detector circuit, FIG. 3(b) showing a time change of an output voltage Vcp+ of a positive-side comparator, FIG. 3(c) showing a time change of an output voltage Vcp− of a negative-side comparator, and FIG. 3(d) showing a time change of an output voltage Vout of an operational amplifier; and

FIG. 4 is a timing chart in the electric circuit in FIG. 2 when an electric leak is occurring, that is, when one of electric wires has a larger current, FIG. 4(a) showing a time change of the coil current Ic detected by the current detector circuit, FIG. 4(b) showing a time change of the output voltage Vcp+ of the positive-side comparator, FIG. 4(c) showing a time change of the output voltage Vcp− of the negative-side comparator, and FIG. 4(d) showing a time change of the output voltage Vout of the operational amplifier; and

FIG. 5 is a timing chart in the electric circuit in FIG. 2 when an electric leak is occurring, that is, when the other electric wire has a larger current, FIG. 5(a) showing a time change of the coil current Ic detected by the current detector circuit, FIG. 5(b) showing a time change of the output voltage Vcp+ of the positive-side comparator, FIG. 5(c) showing a time change of the output voltage Vcp− of the negative-side comparator, and FIG. 5(d) showing a time change of the output voltage Vout of the operational amplifier.

### DETAILED DESCRIPTION

Hereinafter, an embodiment of the present invention will be described with reference to the drawings.

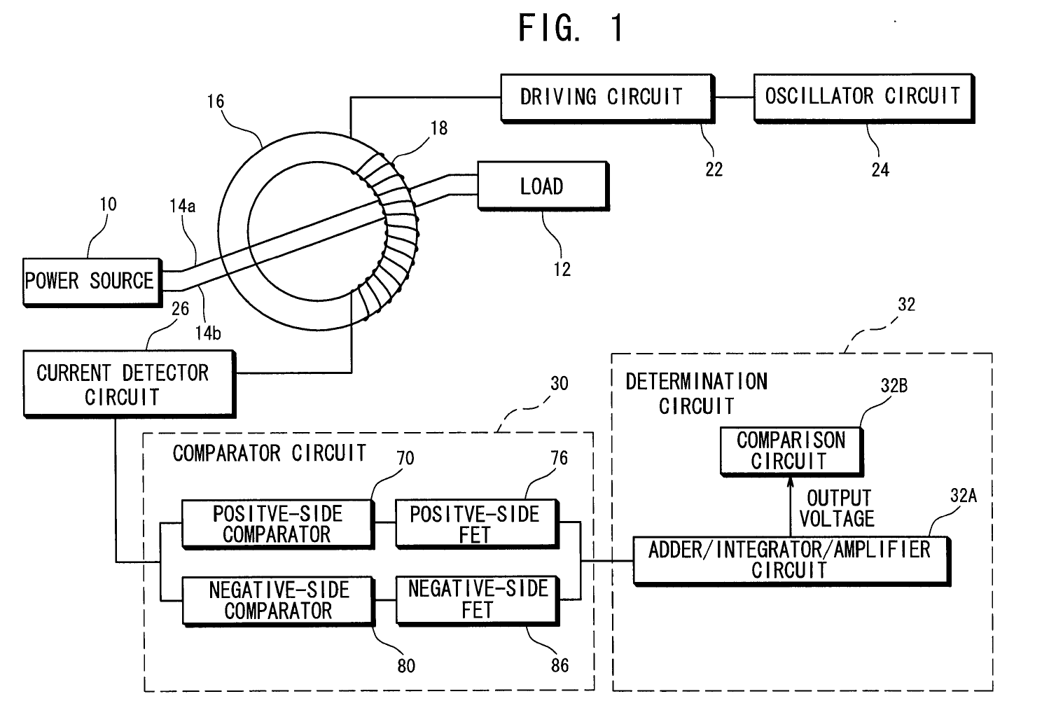

FIG. 1 is a block diagram showing a schematic structure of a flux-gate leakage current sensor of one embodiment. The flux-gate leakage current sensor is applied to one set of electric wires 14a, 14b (hereinafter, they will be comprehensively referred to simply as an electric wire 14) connecting a power source 10 and a load 12, and detects whether or not an electric leak is occurring between the power source 10 and the load 12.

Note that the power source 10 includes a power generator such as, for example, a solar photovoltaic power generator, and the load 12 includes a storage battery storing generated electricity.

The flux-gate leakage current sensor has a core 16 made of a magnetic material such as a permalloy or sendust. The core 16 has, for example, a flat annular shape, and has about several cm inside and outside diameters and an about several mm thickness. The wire 14 is inserted to the center hole of the core 16.

A coil 18 is wound around the core 16 spirally so as to extend along a circumferential direction of the core 16, and the number of times the coil 18 is wound is about 500, for instance. When a current is supplied to the coil 18, lines of magnetic force extend inside the core 16 so as to come full circle.

A driving circuit 22 is connected to the coil 18, and the driving circuit 22 operates in cooperation with an oscillator circuit 24 to apply a voltage with a positive/negative symmetric rectangular wave to the coil 18. That is, a positive peak value and a negative peak value of the rectangular wave are equal, and a duty ratio of the rectangular wave is substantially 50%.

Further, a current detector circuit 26 is connected to the coil 18, and the current detector circuit 26 detects the current flowing in the coil 18 (coil current). The current detector circuit 26 is connected to a comparator circuit 30 and outputs a voltage (measured voltage) corresponding to the coil current to the comparator circuit 30.

Then, the comparator circuit 30 compares the measure voltage with a positive-side reference voltage and a negative-side reference voltage which are positive/negative symmetric to each other, and outputs a positive-side electric signal corresponding to a period in which the measured voltage is higher than the positive-side reference voltage and a negative-side electric signal corresponding to a period in which the measured voltage is lower than the negative-side reference voltage.

Note that absolute values of the positive-side reference voltage and the negative-side reference voltage are substantially equal, and the positive-side reference voltage and the negative-side reference voltage have opposite polarities.

A determination circuit 32 is connected to the comparator circuit 30, and the determination circuit 32 determines a magnitude relation between a current flowing in the electric wire 14a and a current flowing in the electric wire 14b, based on the positive-side electric signal and the negative-side electric signal. When the current flowing in the electric wire 14a and the current flowing in the electric wire 14b are different, it is determined that an electric leak is occurring.

Concretely, for example, when a 30 mA leak is occurring while a 60 A current is flowing in the electric wire 14, the electric leak is detected by the flux-gate leakage current sensor.

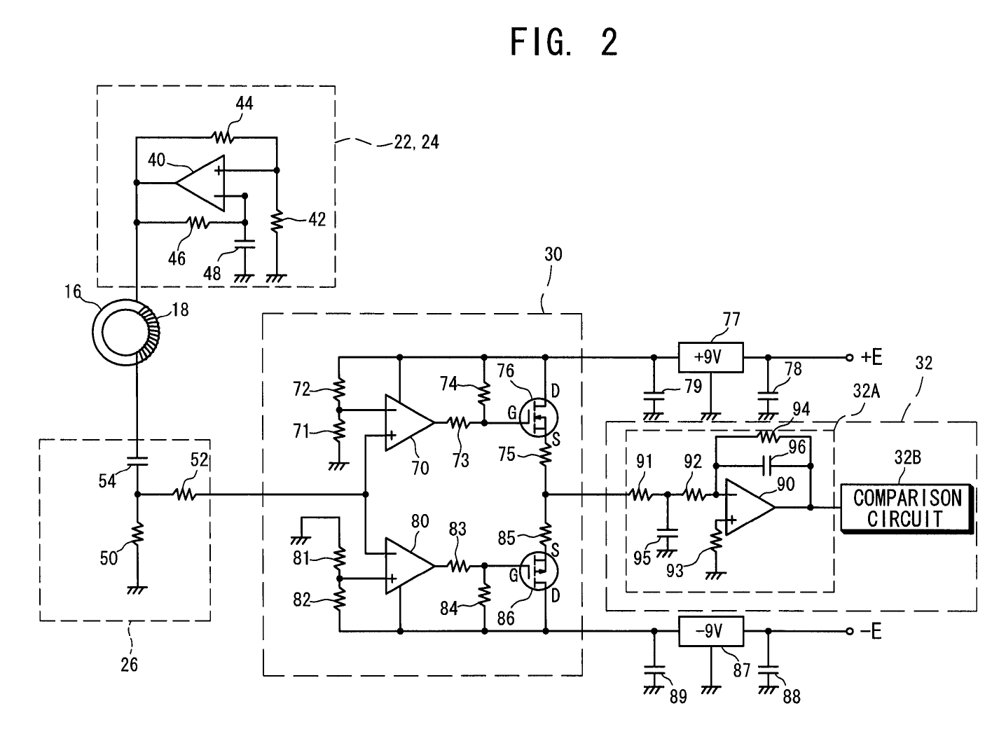

FIG. 2 is a schematic electric circuit diagram of the flux-gate leakage current sensor.

The driving circuit 22 and the oscillator circuit 24 are formed by, for example, an operational amplifier 40, resistors 42, 44, 46, and a capacitor 48, and an output terminal of the operational amplifier 40 is connected to one end of the coil 18. In this case, according to charge/discharge of the capacitor 48, an output voltage of the operational amplifier 40 changes discontinuously between a positive-side saturation output voltage Es and a negative-side saturation output voltage −Es, so that the rectangular wave voltage is supplied to the coil 18.

The current detector circuit 26 is formed by resistors 50, 52 and a capacitor 54, for instance. The other end of the coil 18 is grounded via the capacitor 54 and the resistor 50, and the resistor 52 is connected to the capacitor 54 in parallel with the resistor 50. The coil current flowing in the coil 18 is supplied to the comparator circuit 30 via the resistor 52.

The comparator circuit 30 is formed by, for example, a positive-side comparator 70, a negative-side comparator 80, resistors 71, 72, 73, 74, 75, 81, 82, 83, 84, 85, an n-channel positive-side field-effect transistor (positive-side FET) 76, and a p-channel negative-side field-effect transistor (negative-side FET) 86.

A three-terminal regulator 77 of +9V and a three-terminal regulator 87 of −9V, for instance, are connected as positive/negative symmetric power sources to the comparator circuit 30, and input terminals and output terminals of the three-terminal regulators 77, 87 are grounded via capacitors 78, 79, 88, 89 respectively.

Further, the output terminal of the three-terminal regulator 77 is grounded via the resistors 72, 71 and is also connected to a + power supply terminal of the positive-side comparator 70. Further, the output terminal of the three-terminal regulator 77 is connected to a drain electrode of the positive-side FET 76 and is also connected to a gate electrode of the positive-side FET 76 via the resistor 74.

A non-inverting input terminal (+input terminal) of the positive-side comparator 70 is connected to the resistor 52 of the current detector circuit 26, and an inverting input terminal (−input terminal) of the positive-side comparator 70 is connected to the resistor 72 in parallel with the resistor 71. Further, an output terminal of the positive-side comparator 70 is connected to the gate electrode of the positive-side FET 76 via the resistor 73.

Symmetrically, the output terminal of the three-terminal regulator 87 is grounded via the resistors 82, 81 and is also connected to a -power supply terminal of the negative-side comparator 80. Further, the output terminal of the three-terminal regulator 87 is connected to a drain electrode of the negative-side FET 86 and is also connected to a gate electrode of the negative-side FET 86 via the resistor 84.

An inverting input terminal (−input terminal) of the negative-side comparator 80 is connected to the resistor 52 of the current detector circuit 26 in parallel with the non-inverting input terminal (+input terminal) of the positive-side comparator 70, and a non-inverting input terminal (+input terminal) of the negative-side comparator 80 is connected to the resistor 82 in parallel with the resistor 81. Further, an output terminal of the negative-side comparator 80 is connected to the gate electrode of the negative-side FET 86 via the resistor 83.

The aforesaid positive-side comparator 70, resistors 71, 72, 73, 74, 75, and positive-side field-effect transistor (positive-side FET) 76 form a positive-side part of the comparator circuit 30, and the aforesaid negative-side comparator 80, resistors 81, 82, 83, 84, 85, and negative-side field-effect transistor (negative-side FET) 86 form a negative-side part of the comparator circuit 30 positive/negative symmetric to the positive-side part.

The determination circuit 32 is formed by, for example, an adder/integrator/amplifier circuit 32A and a comparison circuit 32B.

The adder/integrator/amplifier circuit 32A is composed of an operational amplifier 90, resistors 91, 92, 93, 94, and capacitors 95, 96, and a source electrode of the positive-side FET 76 and a source electrode of the negative-side FET 86 are connected to an inverting input terminal of the operational amplifier 90 via the resistors 91, 92 and are also grounded via the resistor 91 and the capacitor 95.

Further, a non-inverting input terminal of the operational amplifier 90 is grounded via the resistor 93, and the inverting input terminal and an output terminal of the operational amplifier 90 are connected via the resistor 94 and the capacitor 96 which are parallel with each other. The output terminal of the operational amplifier 90 is connected to the comparison circuit 32B, and the comparison circuit 32B detects the occurrence of an electric leak based on an output voltage of the operational amplifier 90.

Hereinafter, the operation of the above-described flux-gate leakage current sensor will be described.

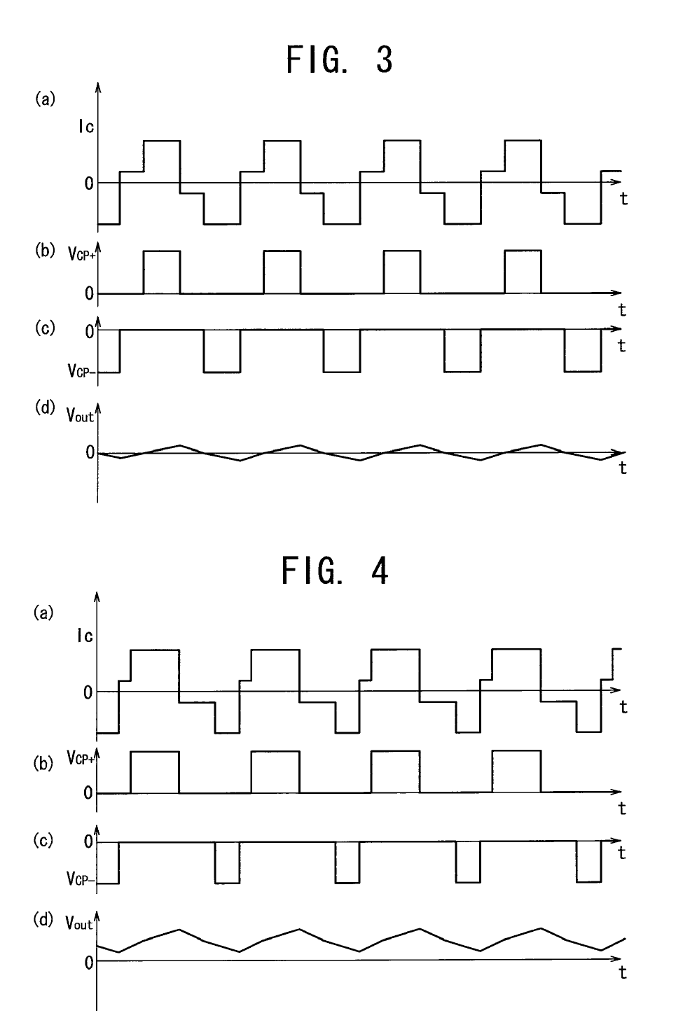

FIG. 3 is a timing chart showing the operation when there is no electric leak, FIG. 3(a) showing a time change of a coil current Ic detected by the current detector circuit 26, FIG. 3(b) showing a time change of an output voltage Vcp+ of the positive-side comparator 70, FIG. 3(c) showing a time change of an output voltage Vcp− of the negative-side comparator 80, and FIG. 3(d) showing a time change of an output voltage Vout of the operational amplifier 90.

As shown in FIG. 3(a), when there is no electric leak, magnetic fields generated by the currents flowing in the electric wires 14a, 14b cancel each other and thus the coil current Ic becomes positive/negative symmetric. The positive-side comparator 70 compares the measured voltage corresponding to the coil current Ic with a positive-side reference voltage, and outputs a constant voltage during a period in which the measured voltage is higher than the positive-side reference voltage as shown in FIG. 3(b).

Similarly, the negative-side comparator 80 compares the measured voltage corresponding to the coil current Ic with a negative-side reference voltage and outputs a constant voltage during a period in which the measured voltage is lower than the negative-side reference voltage as shown in FIG. 3(c).

Absolute values of the constant voltages output by the positive-side comparator 70 and the negative-side comparator 80 respectively are substantially equal, and when there is no electric leak, the output voltage Vcp+ of the positive-side comparator 70 and the output voltage Vcp− of the negative-side comparator 80 are also positive/negative symmetric to each other.

Since a drain voltage (9 V) of the positive-side FET 76 and a drain voltage (−9 V) of the negative-side FET 86 are positive/negative symmetric to each other, a drain current of the positive-side FET 76 (positive-side electric signal) and a drain current of the negative-side FET 86 (negative-side electric signal) are also positive/negative symmetric to each other. The output voltage Vout of the operational amplifier 90 is substantially zero as shown in FIG. 3(d) since the output voltage Vout is equal to an amplified value of a voltage corresponding to the sum of the addition of these drain currents.

On the other hand, FIG. 4 shows a timing chart when an electric leak is occurring and one of the currents flowing in the electric wires 14a, 14b becomes relatively larger.

Concretely, in FIG. 4(a), due to the occurrence of the electric leak, the magnetic fields generated by the currents flowing in the electric wires 14a, 14b do not cancel each other and the positive side of the coil current Ic becomes larger than its negative-side.

Therefore, as shown in FIG. 4(b) and FIG. 4(c), the period in which the positive-side comparator 70 outputs the constant voltage becomes longer than the period in which the negative-side comparator 80 outputs the constant voltage. As a result, as shown in FIG. 4(d), the output voltage Vout of the operational amplifier 90 has a limited value larger than the substantially zero value.

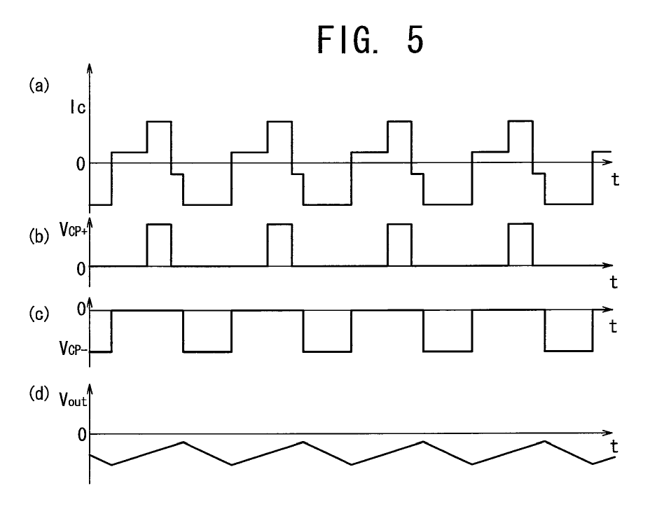

Similarly, FIG. 5 also shows a timing chart when an electric leak is occurring, but FIG. 5, contrary to FIG. 4, shows a timing chart when the other one of the currents flowing in the electric wires 14a, 14b becomes relatively larger. In this case, as shown in FIG. 5(d), the output voltage Vout of the operational amplifier 90 has a limited value smaller than the substantially zero value.

Therefore, the comparison circuit 32B of the determination circuit 32 is capable of detecting the occurrence of the electric leak based on the output voltage Vout.

According to the flux-gate leakage current sensor of the embodiment described above, based on the period in which the measured voltage is higher than the positive-side reference voltage and the period in which the measured voltage is lower than the negative-side reference voltage, the magnitude relation between the currents flowing in the electric wires 14a, 14b is determined. That is, based on the period in which the measured voltage is higher than the positive-side reference voltage and the period in which the measured voltage is lower than the negative-side reference voltage, the electric leak is detected.

According to this flux-gate leakage current sensor, since the positive/negative symmetric voltage is applied so that the density of the magnetic flux of the core 16 saturates while the magnetic flux is reversing, the coil current Ic flowing in the coil 18 is not influenced by a hysteresis of the density of the magnetic flux of the core 16.

Further, since the positive/negative symmetric voltage is applied so that the density of the magnetic flux of the core 16 saturates while the magnetic flux is reversing, even when magnetic permeability of the core 16 changes due to temperature, the relative relation between the period in which the measured voltage is higher than the positive-side reference voltage and the period in which the measured voltage is lower than the negative-side reference voltage is maintained.

As a result of the above, the flux-gate leakage current sensor detects the electric leak highly accurately over a wide temperature range.

Further, according to the flux-gate leakage current sensor, a gate voltage with a shaped waveform is applied to the positive-side field-effect transistor 76 in correspondence to the period in which the measured voltage is higher than the positive-side reference voltage. Further, a gate voltage with a shaped waveform is applied to the negative-side field-effect transistor 86 in correspondence to the period in which the measured voltage is lower than the negative-side reference voltage.

According to the flux-gate leakage current sensor, accuracy in leak detection is improved owing to the aforesaid application of the gate voltages with the shaped waveforms.

The present invention is not limited to the above-described embodiment and can be variously modified. The circuit structures described with reference to the drawings in the embodiment are only preferable examples, and it goes without saying that even when various elements are added or part thereof are replaced in the basic circuit structures, the present invention can be suitably embodied.

What is claimed is:

1. A flux-gate leakage current sensor comprising:
an annular core to which a first electric wire and a second electric wire as targets of measurement are to be inserted;
a coil wound around said core;
a driving circuit which applies to said coil a voltage with a positive/negative symmetric rectangular wave so as to saturate a density of a magnetic flux of said coil while reversing a direction of the magnetic flux;
a comparator circuit which compares a measured voltage changing according to a coil current flowing in said coil with a positive-side reference voltage and a negative-side reference voltage that are positive/negative symmetric to each other, and outputs a positive-side electric signal corresponding to a period in which the measured voltage is higher than the positive-side reference voltage and a negative-side electric signal corresponding to a period in which the measured voltage is lower than the negative-side reference voltage; and
a determination circuit which compares the positive-side electric signal and the negative-side electric signal output from said comparator circuit.

2. The flux-gate leakage current sensor according to claim 1,
wherein said comparator circuit includes:
a positive-side comparator having a non-inverting input terminal to which the measured voltage is applied and an inverting input terminal to which the positive-side reference voltage is input;
a negative-side comparator having an inverting input terminal to which the measured voltage is applied and a non-inverting input terminal to which the negative-side reference voltage is input; and
a positive-side field-effect transistor having a gate electrode to which an output voltage of said positive-side comparator is input; and
a negative-side field effect transistor having a gate electrode to which an output voltage of said negative-side comparator is input, and
wherein said determination circuit includes an integrator circuit which adds drain currents of said positive-side field-effect transistor and said negative-side field-effect transistor and outputs a voltage corresponding to an integration amount of the added drain currents.
